(19) United States
(12) Patent Application Publication
(10) Pub. No.: US 2015/0240356 A1
(43) Pub. Date: Aug. 27, 2015

(54) INLET SYSTEM FOR METAL-ORGANIC CHEMICAL VAPOR DEPOSITION APPARATUS

(71) Applicant: National Central University, Jhongli City (TW)

(72) Inventors: Jyh-Chen CHEN, Jhongli City (TW); Ching-Hsin CHANG, Jhongli City (TW)

(73) Assignee: National Central University, Jhongli City (TW)

(21) Appl. No.: 14/252,166

(22) Filed: Apr. 14, 2014

(30) Foreign Application Priority Data
Feb. 26, 2014 (TW) TW 103106593

(51) Int. Cl. C23C 16/455

(52) U.S. Cl. CPC C23C 16/455

(57) ABSTRACT

An inlet system for a metal-organic chemical vapor deposition (MOCVD) apparatus is provided. The inlet system includes an inlet module and a subsidiary inlet module. The inlet module admits a reactant gas. The subsidiary inlet module admits a carrier gas. The subsidiary inlet module is disposed outside the inlet module to reduce turbulent flow, prevent the reactant gas from contaminating the inner wall of a reactor chamber, and concentrate the reactant gas, so as to enhance the reaction rate of the reactant gas and the growth rate of films.

### BACKGROUND OF THE INVENTION

1. Technical Field

The present invention relates to inlet systems, and more particularly, to an inlet system for a metal-organic chemical vapor deposition (MOCVD) apparatus.

2. Description of Related Art

Metal-organic chemical vapor deposition (MOCVD), or known as metal-organic chemical vapor phase epitaxy (MOVPD), is a semiconductor thin-film preparation technique for use in preparing semiconductor thin-films from III-V compounds, II-VI compounds, and alloys thereof, such as gallium nitride, gallium arsenide, indium phosphide, and zinc oxide. As semiconductor thin-films have increasingly wide application, the manufacturing of light-emitting diodes (LED), laser diodes (LD), and radio frequency integrated circuit (RF IC) usually requires MOCVD apparatuses; hence, MOCVD apparatuses are attributed to one of the important types of semiconductor process apparatuses.

The underlying principle of MOCVD involves converting a precursor into a gas and then delivering a reactant gas together with a carrier gas to a reactor through an inlet system, such that a solid-state substance produced as a result of a chemical reaction deposits on a solid-state substrate positioned on a rotatable heating platform, thereby allowing a semiconductor thin-film to be formed on the solid-state substrate. During the deposition process, it is important to control the thickness, and the uniformity thereof, of the semiconductor thin-film. However, turbulent flow, which occurs to the reactor because of thermal buoyancy and inertial force, is an important factor in causing uneven thickness of the semiconductor thin-film. Furthermore, the turbulent flow causes the contamination of the inner wall of the reactor chamber and a waste of the precursor.

The aforesaid phenomena can be prevented by means of process parameter control, the shape of a nozzle of the inlet system, and the type of the reactor. At present, MOCVD apparatus inlet systems used by the industrial sector come in three types. The first type of MOCVD apparatus inlet systems operates in a vertical inlet mode and relies upon the high-speed and yet axial-rotation-free rotation of a platform to ensure uniform flow, increases the yield effectively, and reduces the duration and frequency of rinsing and maintenance. However, not only is the reactor bulky, but the required amount of the reactant gas is also excessive, not to mention that turbulent flow is likely to occur to the reactor and thus cause instability.

The second type of MOCVD apparatus inlet systems operates in a central nozzle mode and relies upon the low-speed rotation of a platform as well as the axial rotation of a wafer to ensure stable flow. It has advantages, namely a compact reactor, and efficient use of the reactant gas in terms of the required amount thereof But the reactor chamber of the reactor is so low to render automation difficult. Moreover, the reactor must be opened after each instance of the manufacturing process, thereby bringing about a change in the subsequent manufacturing process environment. Furthermore, due to deposition and contamination, the axial-rotation of the platform often speeds up, slows down, or even stops during the epitaxy process, thereby changing growth conditions and causing uneven thickness of the thin-film grown.

The third type of MOCVD apparatus inlet systems operates in an inlet mode characterized by a shower nozzle and relies upon the low and medium-speed rotation of a platform to ensure uniform intake. However, the aforesaid inlet mode is characterized disadvantageously be a small distance (of 20 mm approximately) between an intake port and the platform, a high likelihood of clogging the apertures of the shower nozzle, and thus the necessity to clean or change the shower nozzle regularly.

The above analysis indicates that conventional inlet systems for use with MOCVD apparatuses each have advantages and disadvantages. However, the past enhancement of the uniformity of flow inside the reactor chamber is mainly achieved by altering the means of intake and designing the geometrical shapes of intake ports as well as an array in which the intake ports are arrange. Nonetheless, some disadvantages remain unsolved, including: in the reactor chamber, the reactant gas forms unstable turbulent flow; the reactant gas undergoes a pre-reaction in the vicinity of the intake ports to form products at the intake ports, thus clogging the intake ports; and the turbulent flow causes the contamination of the inner wall of the reactor chamber and a waste of precursors.

### BRIEF SUMMARY OF THE INVENTION

The present invention relates to an inlet system for use with a metal-organic chemical vapor deposition (MOCVD) apparatus. The inlet system includes a subsidiary inlet module disposed outside an inlet module to reduce turbulent flow and concentrate a reactant gas, so as to not only enhance the reaction rate of the reactant gas and the growth rate of films but also enhance the uniformity of film growth.

The present invention provides an inlet system for a metal-organic chemical vapor deposition (MOCVD) apparatus, comprising: an inlet module for admitting at least a reactant gas; and a subsidiary inlet module disposed outside the inlet module, including at least a subsidiary inlet channel, and admitting a carrier gas.

The present invention also provides an inlet system for a metal-organic chemical vapor deposition (MOCVD) apparatus, comprising: an inlet module including at least a first reacting gas channel for admitting a first reactant gas and at least a second reacting gas channel for admitting a second reactant gas; and a subsidiary inlet module including at least a subsidiary inlet channel adapted to admit a carrier gas and disposed between the at least a first reacting gas channel and the at least a second reacting gas channel to separate the at least a first reacting gas channel and the at least a second reacting gas channel.

Implementation of the present invention involves the following inventive steps:

1. enhance the reaction rate of a reactant gas and the growth rate of a thin-film;

2. reduce formation of turbulent flow and thus enhance the uniformity and stability of the growth of the thin-film; and

3. reduce pollution, decrease the required frequency of the rinsing and maintenance of a reactor chamber, enhance the utilization rate of the apparatus, and cut the production costs thereof

### BRIEF DESCRIPTION OF THE SEVERAL VIEWS OF THE DRAWINGS

The invention as well as a preferred mode of use and advantages thereof will be best understood by referring to the following detailed description of an illustrative embodiment in conjunction with the accompanying drawings, wherein:

FIG. 1 is a schematic view of a reactor chamber and an inlet system according to an embodiment of the present invention;

FIG. 2 is a schematic view of an inlet system for an MOCVD apparatus according to an embodiment of the present invention;

FIG. 3 is a schematic view of an inlet system with a subsidiary inlet module including at least two subsidiary inlet channels according to an embodiment of the present invention;

FIG. 4 is a schematic view of an inlet system with a subsidiary inlet channel including separate linear intake ports according to an embodiment of the present invention;

FIG. 5 is a schematic view of an inlet system with a subsidiary inlet channel including separate dotted intake ports according to an embodiment of the present invention;

FIG. 6 is a schematic view of another inlet system for an MOCVD apparatus according to an embodiment of the present invention;

FIG. 7 is a schematic view of an inlet system with first and second reacting gas channels including linear intake ports according to an embodiment of the present invention;

FIG. 8 is a schematic view of the inlet system shown in FIG. 7 and further including a peripheral intake port;

FIG. 9 is a schematic view of an inlet system with a subsidiary inlet channel including radiately-arranged linear intake ports according to an embodiment of the present invention;

FIG. 10 is a schematic view of the inlet system shown in FIG. 9 and further including a peripheral intake port;

FIG. 11 is a schematic view of an inlet system with a subsidiary inlet channel including parallel linear intake ports according to an embodiment of the present invention;

FIG. 12 is a schematic view of the inlet system shown in FIG. 11 and further including a peripheral intake port;

FIG. 13 is a schematic view of an inlet system with a subsidiary inlet channel including transverse linear intake ports and longitudinal linear intake ports which are in contact with each other, respectively, according to an embodiment of the present invention; and

FIG. 14 is a schematic view of the inlet system shown in FIG. 13 and further including a peripheral intake port.

### DETAILED DESCRIPTION OF THE INVENTION

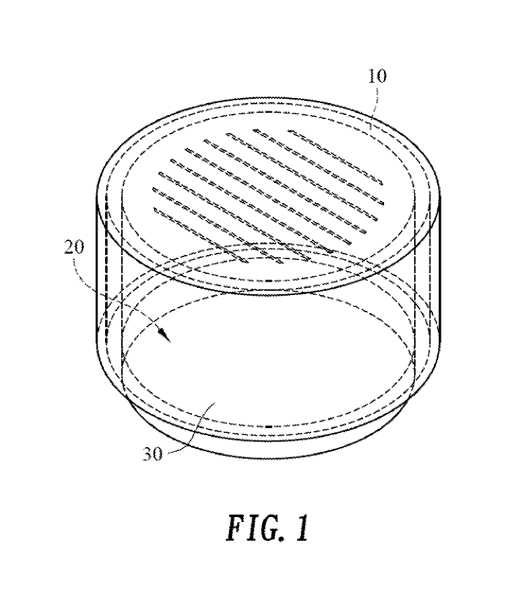

Referring to FIG. 1, there is shown a schematic view of a reactor chamber 20 and an inlet system 10 according to an embodiment of the present invention. A platform 30, which is rotatable and serves a heating purpose, is disposed at a lower portion of the reactor chamber 20. A solid-state substrate is disposed on the platform 30. The inlet system 10 is disposed above the platform 30 and adapted to admit a reactant gas and a carrier gas.

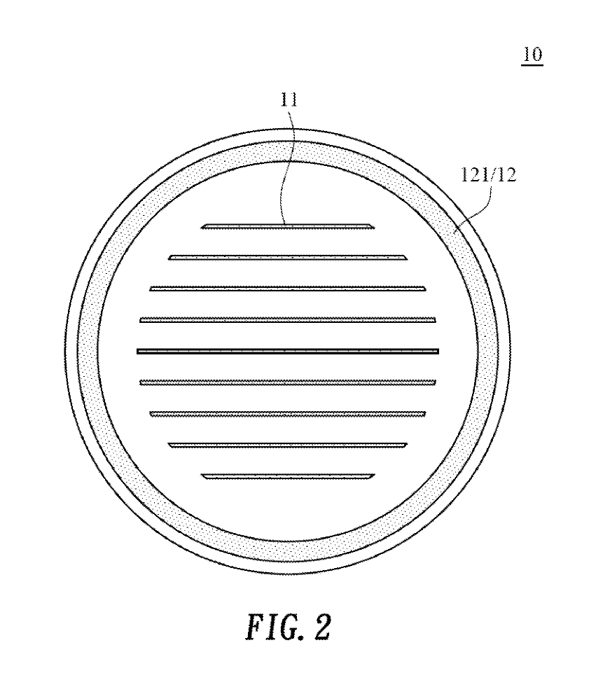

Referring to FIG. 1 and FIG. 2, in an embodiment of the present invention, the inlet system 10 is for use with a metal-organic chemical vapor deposition (MOCVD) apparatus and comprises an inlet module 11 and a subsidiary inlet module 12.

The inlet module 11 admits the reactant gas. The carrier gas is delivered together with the reactant gas to the reactor chamber 20 through the inlet module 11. The carrier gas is any gas that does not undergo any chemical reaction with the reactant gas and is exemplified by hydrogen or nitrogen. The reactant gas is exemplified by a single gas composed of a III compound, a V compound, a II compound, or a VI compound, by a mixture of gases composed of a mixture of a III compound and a V compound, or by a mixture of gases composed of a mixture of a II compound and a VI compound.

The subsidiary inlet module 12 admits the carrier gas only and is disposed outside the inlet module 11. The carrier gas admitted into the subsidiary inlet module 12 can be either identical to or different from the carrier gas for use in delivering the reactant gas in the inlet module 11 so long as the carrier gas admitted into the subsidiary inlet module 12 does not undergo any chemical reaction with the reactant gas.

The subsidiary inlet module 12 comprises at least a subsidiary inlet channel 121. Intake ports of the subsidiary inlet channel 121 surround intake ports of the inlet system 10 and are positioned proximate to the inner wall of the reactor chamber 20. The carrier gas is delivered to the reactor chamber through the subsidiary inlet module 12; hence, the carrier gas reduces turbulent flow near the inner wall of the reactor chamber, prevents the reactant gas from contaminating the inner wall of the reactor chamber, and concentrates the reactant gas, thereby achieving the effective use of the reactant gas.

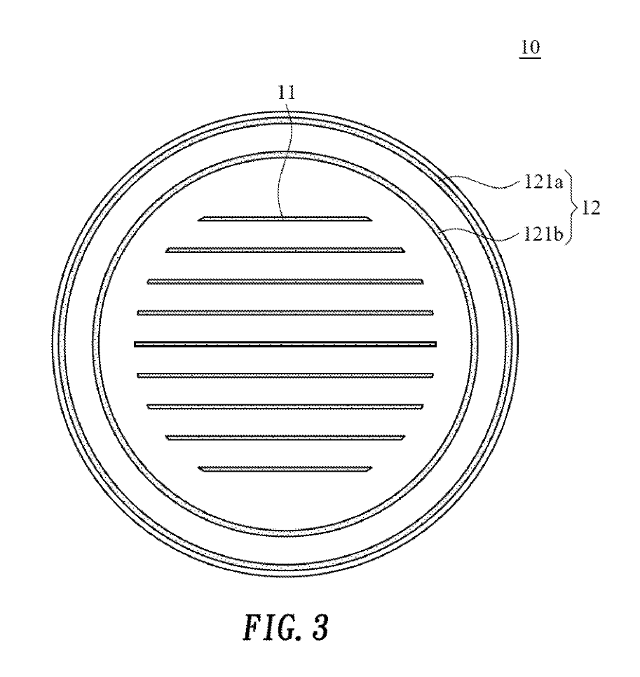

Referring to FIG. 3, the subsidiary inlet module 12 comprises at least two subsidiary inlet channels, namely a first subsidiary inlet channel 121a and a second subsidiary inlet channel 121b. Intake ports of the first subsidiary inlet channel 121a are disposed outside intake ports of the second subsidiary inlet channel 121b. Intake ports of the second subsidiary inlet channel 121b are disposed outside intake ports of the inlet module 11. The intake ports of the second subsidiary inlet channel 121b surround the intake ports of the inlet module 11 so as to reduce turbulent flow, narrow the scope of intake, and enhance the utilization rate of the reactant gas. The first subsidiary inlet channel 121a disposed outside the second subsidiary inlet channel 121b is positioned proximate to the inner wall of the reactor chamber 20, so as to reduce turbulent flow at a peripheral area and prevent the reactant gas from contaminating the inner wall of the reactor chamber 20.

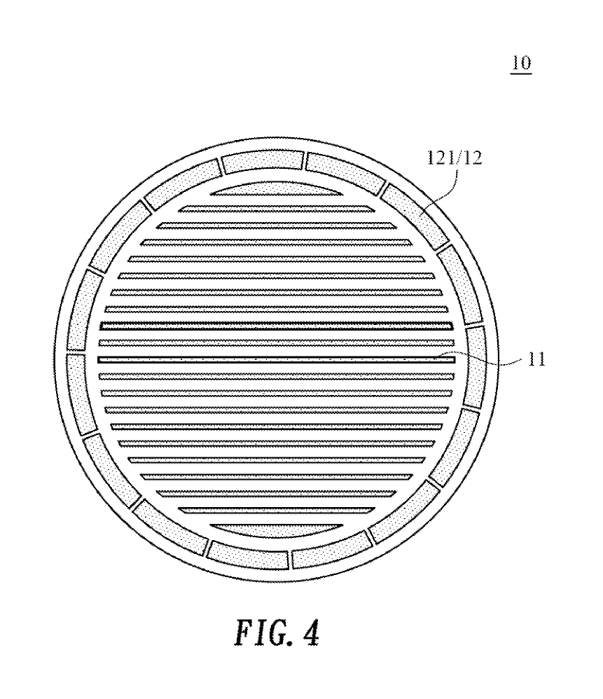

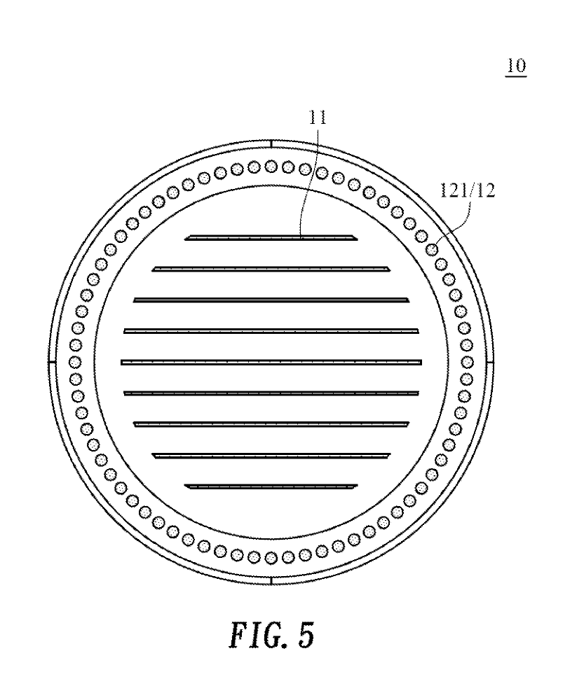

The subsidiary inlet channel 121, 121a, 121b of the subsidiary inlet module 12 illustrated with both FIG. 2 and FIG. 3 each have an annular intake port for enabling uninterrupted intake and formation a gas wall, so as to fully surround the intake ports of the inlet module 11. Alternatively, referring to FIG. 4 and FIG. 5, the subsidiary inlet channel 121 has separate linear intake ports or separate dotted intake ports, such that the separate linear intake ports or the separate dotted intake ports surround the inlet module 11, so as to reduce turbulent flow and prevent the reactant gas from contaminating the inner wall of the reactor chamber.

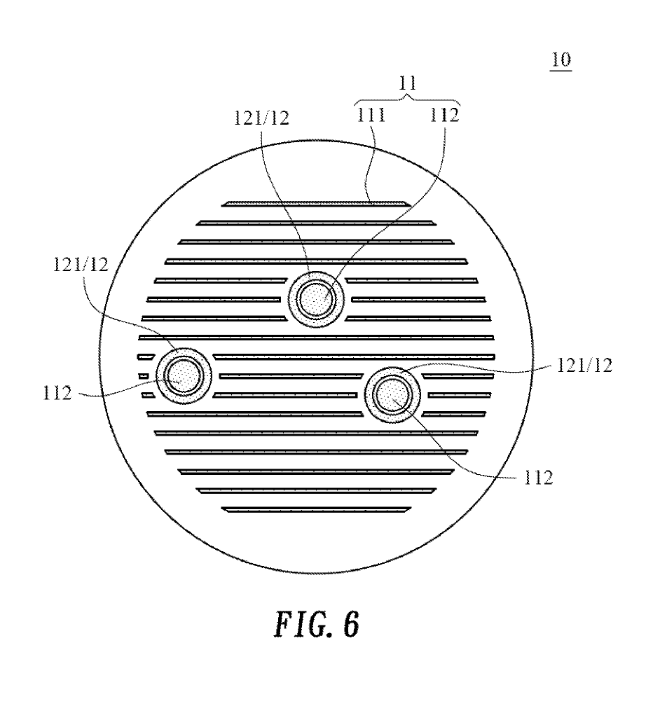

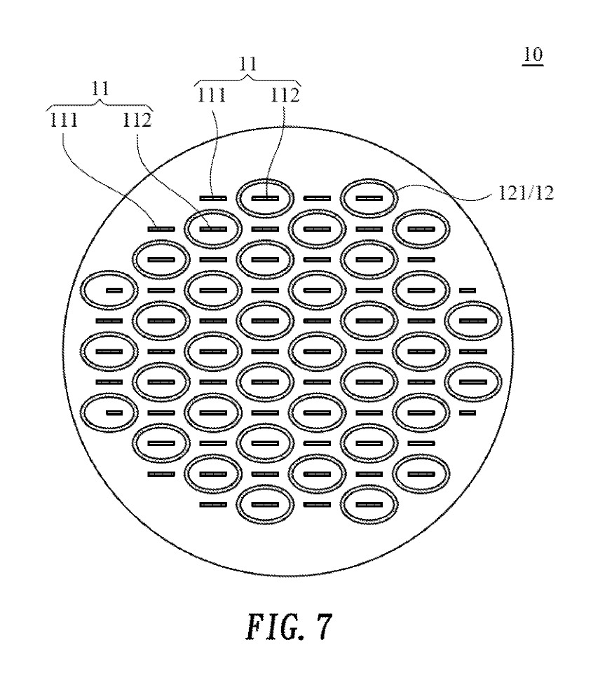

Referring to FIG. 6 and FIG. 7, another inlet module 11 comprises at least a first reacting gas channel 111 and at least a second reacting gas channel 112. The first reacting gas channel 111 admits a first reactant gas. The second reacting gas channel 112 admits a second reactant gas. The first reactant gas is exemplified by a III compound gas, and the second reactant gas is exemplified by a V compound gas; alternatively, the first reactant gas is exemplified by a V compound gas, and the second reactant gas is exemplified by a III compound gas. In a variant embodiment of the present invention, the first reactant gas is exemplified by a II compound gas, and the second reactant gas is exemplified by a VI compound gas; alternatively, the first reactant gas is exemplified by a VI compound gas, and the second reactant gas is exemplified by a II compound gas.

The first reacting gas channel 111 and the second reacting gas channel 112 of the inlet module 11 each admit a single reactant gas only. Furthermore, each of the intake ports of the first and second reacting gas channels 111, 112 is linear, round, or has any appropriate geometrical shape, which is not restrictive of the present invention.

The subsidiary inlet module 12 comprises at least a subsidiary inlet channel 121 adapted to admit the carrier gas and disposed between the first reacting gas channel 111 and the second reacting gas channel 112 to separate the first reacting gas channel 111 from the second reacting gas channel 112 and thus prevent the first reactant gas and the second reactant gas from undergoing a pre-reaction in the vicinity of the intake ports and clogging the intake ports, reduce formation of particles which cannot form a film at the low and medium temperature areas and thus save the reactant gas, and lessen gas flow instability otherwise caused by an inertial force driven by difference on momentum between fluid flow of the first reactant gas and the second reactant gas.

For instance, the subsidiary inlet channel 121 has at least an annular intake port disposed outside the first reacting gas channel 111 or the second reacting gas channel 112 so as to surround intake ports of the first reacting gas channel 111 or intake ports of the second reacting gas channel 112. Referring to FIG. 6, the annular intake port of the subsidiary inlet channel 121 is disposed outside intake ports of the second reacting gas channel 112, so as to separate the first reacting gas channel 111 from the second reacting gas channel 112.

Referring to FIG. 4 and FIG. 5, in addition to the annular intake port, the subsidiary inlet channel 121 has separate linear intake ports (not shown) or separate dotted intake ports (not shown). Likewise, the separation of the first reactant gas and the second reactant gas can also be achieved by using separate linear intake ports or separate dotted intake ports to surround the intake ports of the first reacting gas channel 111 or the intake ports of the second reacting gas channel 112.

Referring to FIG. 6 and FIG. 7, the intake ports of the first reacting gas channel 111 and the second reacting gas channel 112 fall within two categories in terms of shape, namely linear and round. Referring to FIG. 6, the second reacting gas channels 112 with round intake ports are interposed between the first reacting gas channels 111 with linear intake ports.

Referring to FIG. 7, the intake ports of the first and second reacting gas channels 111, 112 are not only linear but also alternate with each other and are spaced apart from each other. Hence, the first reacting gas channel 111 and the second reacting gas channel 112 each have a plurality of linear intake ports and are arranged in an array. The intake ports of the first reacting gas channel 111 and the second reacting gas channel 112 alternate with each other and are spaced apart from each other. The subsidiary inlet channel 121 is disposed outside the second reacting gas channel 112 having the linear intake ports.

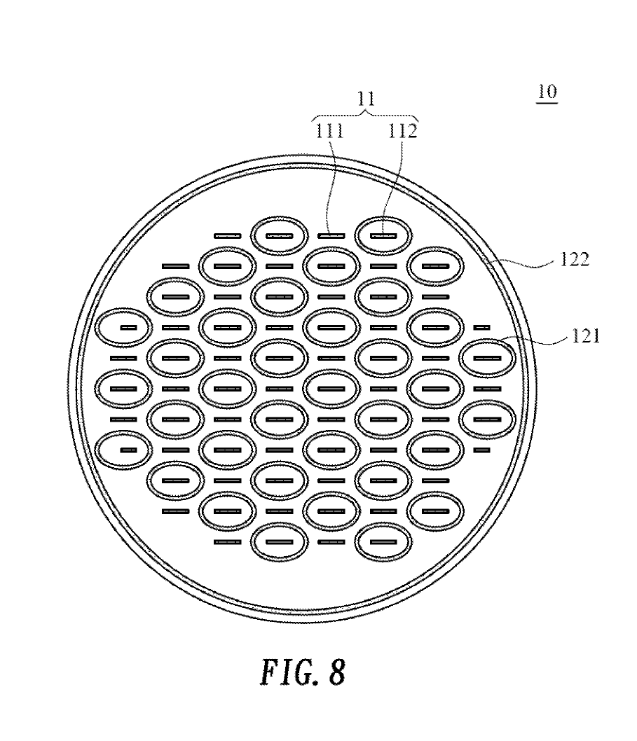

Referring to FIG. 8, the subsidiary inlet channel 121 further comprises at least a peripheral intake port 122 disposed outside the annular intake port, at least a first reacting gas channel 111, and at least a second reacting gas channel 112 to surround the annular intake port of the subsidiary inlet channel 121, the at least a first reacting gas channel 111, and the at least a second reacting gas channel 112.

Hence, the peripheral intake port 122 is disposed outside the intake ports of the inlet system 10 and positioned proximate to the inner wall of the reactor chamber. Referring to FIG. 8, the peripheral intake port 122 is provided in the form of consecutive peripheral annular intake ports conducive to uninterrupted intake and formation a gas wall, so as to fully surround the intake ports of the inlet module 11. Alternatively, the configuration of the peripheral intake port 122 includes, as illustrated with FIG. 4 and FIG. 5, separate linear intake ports or separate dotted intake ports, such that the separate linear intake ports or the separate dotted intake ports surround the inlet module 11 so as to reduce turbulent flow and prevent the reactant gas from contaminating the inner wall of the reactor chamber.

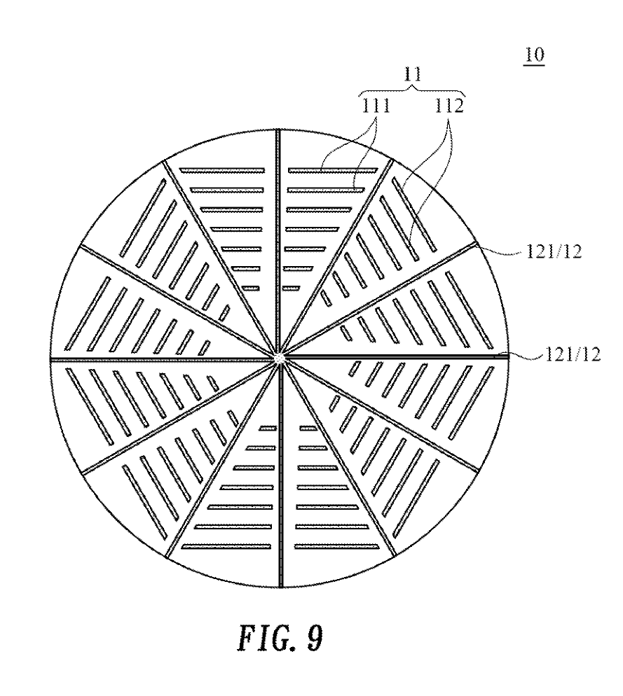

Referring to FIG. 9, the inlet module 11 comprises at least a first reacting gas channel 111 and at least a second reacting gas channel 112. Furthermore, the first reacting gas channel 111 and the second reacting gas channel 112 are positioned radiately and arranged alternately. Hence, the inlet system 10 is defined with a plurality of regions, and each region only has a reacting gas channel. For example, the first region only has the first reacting gas channel 111, whereas the second region only has the second reacting gas channel 112, wherein the first region alternates with the second region. For example, in the same region, intake ports of the first reacting gas channel 111 or intake ports of the second reacting gas channel 112 are parallel, such that the first region which contains the first reacting gas channel 111 and the second region which contains the second reacting gas channel 112 are positioned radiately and arranged alternately. Also, in the same region, the intake ports of the first reacting gas channel 111 or the second reacting gas channel 112 are round in shape (not shown).

The subsidiary inlet module 12 comprises at least a subsidiary inlet channel 121 and a plurality of linear intake ports. The linear intake ports are arranged radiately. Referring to FIG. 9, the linear intake ports are in contact with each other at a point of contact or are separate from each other. The linear intake ports are each disposed between at least a first reacting gas channel 111 and at least a second reacting gas channel 112 and thus function as a line of demarcation between the first region and the second region to separate the first reacting gas channel 111 and the second reacting gas channel 112.

The linear intake ports of the subsidiary inlet channel 121 separate the first reacting gas channel 111 and the second reacting gas channel 112, such that each linear intake port of each said subsidiary inlet channel 121 are flanked by the first reacting gas channel 111 and the second reacting gas channel 112.

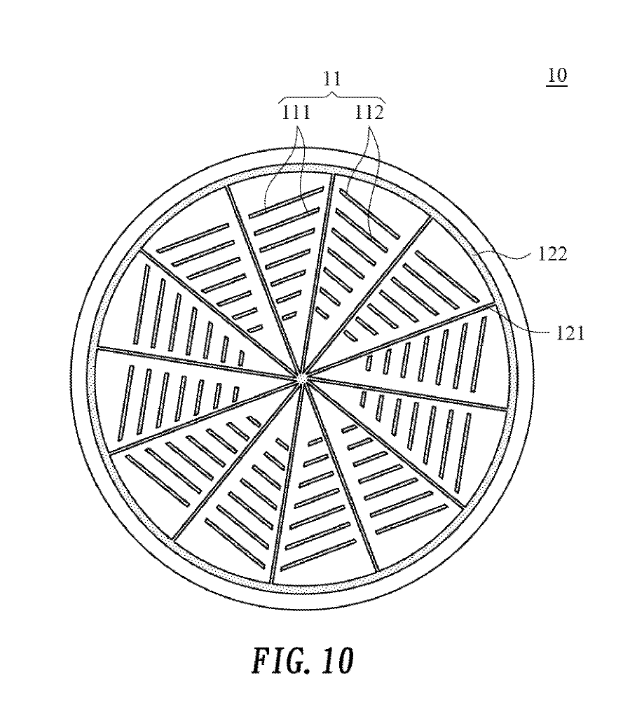

Referring to FIG. 10, the subsidiary inlet channel 121 further comprises the peripheral intake port 122 communicating with the linear intake ports of the subsidiary inlet channel 121 or being separated from the linear intake ports of the subsidiary inlet channel 121. The peripheral intake port 122 is disposed outside at least a first reacting gas channel 111 and at least a second reacting gas channel 112 to surround the first reacting gas channel 111 and the second reacting gas channel 112.

The peripheral intake port 122 is disposed outside intake ports of the inlet system 10 and positioned proximate to the inner wall of the reactor chamber. Referring to FIG. 10, the peripheral intake port 122 is provided in the form of consecutive peripheral annular intake ports conducive to uninterrupted intake and formation a gas wall, so as to fully surround the intake ports of the inlet module 11. Referring to FIG. 4 and FIG. 5, the peripheral intake port 122 is provided in the form of separate linear intake ports or separate dotted intake ports, such that the separate linear intake ports or the separate dotted intake ports surround the inlet module 11 so as to reduce turbulent flow and prevent the reactant gas from contaminating the inner wall of the reactor chamber.

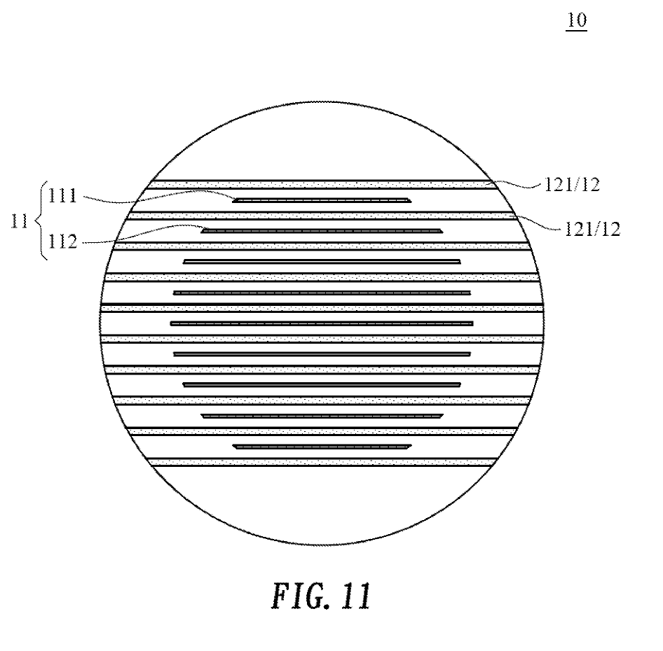

Referring to FIG. 11, the inlet module 11 comprises at least a first reacting gas channel 111 and at least a second reacting gas channel 112. Furthermore, the first reacting gas channel 111 and the second reacting gas channel 112 are parallel and alternate with each other.

The subsidiary inlet module 12 comprises at least a subsidiary inlet channel 121 and a plurality of linear intake ports. The linear intake ports are parallel and are each disposed between at least a first reacting gas channel 111 and at least a second reacting gas channel 112 to separate the first reacting gas channel 111 from the second reacting gas channel 112.

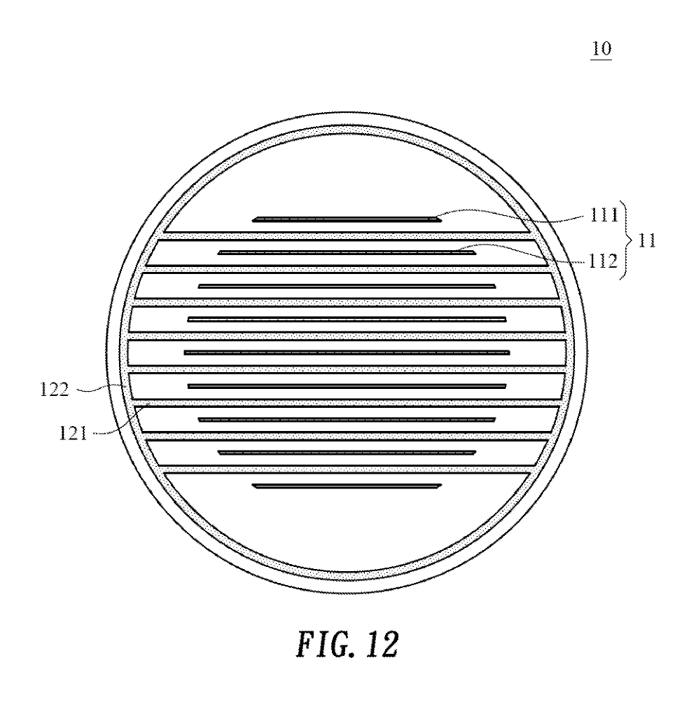

Referring to FIG. 12, the subsidiary inlet channel 121 further comprises a peripheral intake port 122 in communication with the linear intake ports of the subsidiary inlet channel 121. Alternatively, the peripheral intake port 122 is separate from the linear intake ports of the subsidiary inlet channel 121. The peripheral intake port 122 is disposed outside the at least a first reacting gas channel 111 and the at least a second reacting gas channel 112 to surround the linear intake ports of the subsidiary inlet channel 121, the first reacting gas channel 111, and the second reacting gas channel 112.

The peripheral intake port 122 is disposed outside intake ports of the inlet system 10 and positioned proximate to the inner wall of the reactor chamber. Referring to FIG. 12, the peripheral intake port 122 is provided in the form of consecutive peripheral annular intake ports conducive to uninterrupted intake and formation a gas wall, so as to fully surround the intake ports of the inlet module 11. Referring to FIG. 4 and FIG. 5, the peripheral intake port 122 is provided in the form of separate linear intake ports or separate dotted intake ports, such that the separate linear intake ports or the separate dotted intake ports surround the inlet module 11 so as to reduce turbulent flow and prevent the reactant gas from contaminating the inner wall of the reactor chamber.

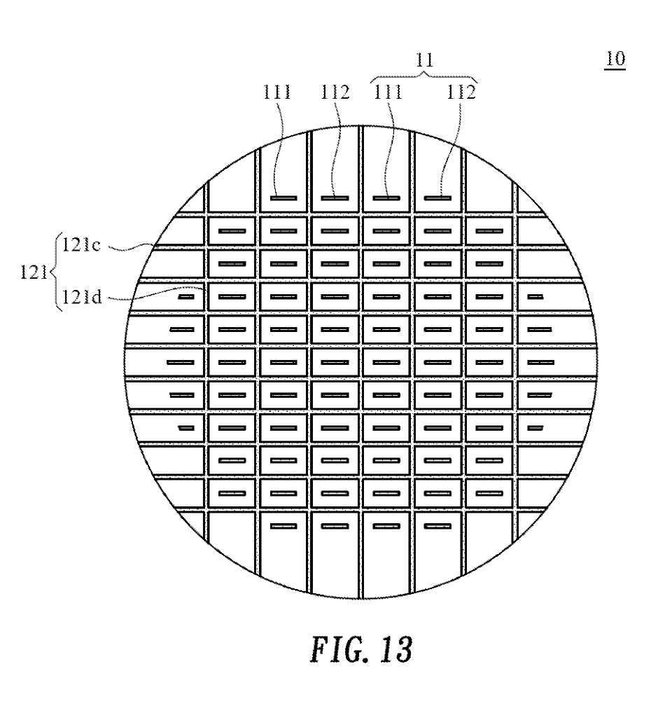

Referring to FIG. 13, the inlet module 11 comprises at least a first reacting gas channel 111 and at least a second reacting gas channel 112. Furthermore, the first reacting gas channel 111 and the second reacting gas channel 112 each have a plurality of intake ports. The intake ports of the first reacting gas channel 11 and the intake ports of the second reacting gas channel 112 are arrange in an array and alternate with each other.

The subsidiary inlet module 12 comprises at least a subsidiary inlet channel 121 and a plurality of transverse linear intake ports 121c and a plurality of longitudinal linear intake ports 121d. The transverse linear intake ports 121c are in contact with the longitudinal linear intake ports 121d, respectively, and surround the intake ports of at least a first reacting gas channel 111 or the intake ports of at least a second reacting gas channel 112 so as to separate the first reacting gas channel 111 and the second reacting gas channel 112.

The transverse and longitudinal linear intake ports 121c, 121d are each flanked by the first reacting gas channel 111 and the second reacting gas channel 112 and adapted to admit the carrier gas into the reactor chamber. Due to the transverse and longitudinal linear intake ports 121c, 121d of the subsidiary inlet channel 121, the reactant gas being discharged from the first and second reacting gas channels 111, 112 can be insulated from the intake ports by the carrier gas, thereby inhibiting the pre-reaction and lessening the likelihood of intake port clogging.

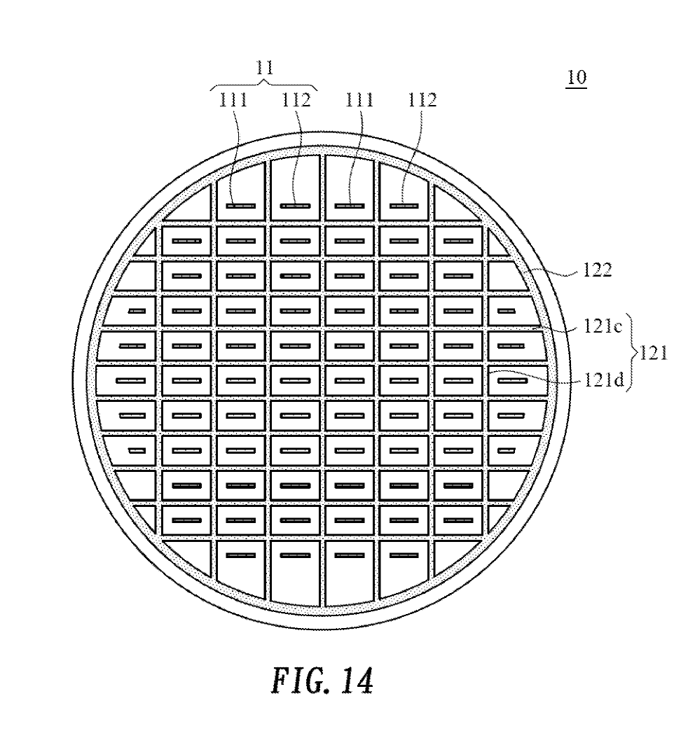

Referring to FIG. 14, the subsidiary inlet channel 121 further comprises a peripheral intake port 122 communicating with the transverse linear intake ports 121c and the longitudinal linear intake ports 121d or being separated from the transverse linear intake ports 121c and the longitudinal linear intake ports 121d. The peripheral intake port 122 is disposed outside at least a first reacting gas channel 111 and at least a second reacting gas channel 112 so as to surround the transverse linear intake ports 121c, the longitudinal linear intake ports 121d, the first reacting gas channel 111, and the second reacting gas channel 112.

Referring to FIG. 14, the peripheral intake port 122 is provided in the form of consecutive peripheral annular intake ports conducive to uninterrupted intake and formation a gas wall, so as to fully surround the intake ports of the inlet module 11. Referring to FIG. 4 and FIG. 5, the peripheral intake port 122 is provided in the form of separate linear intake ports or separate dotted intake ports, such that the separate linear intake ports or the separate dotted intake ports surround the inlet module 11 so as to reduce turbulent flow and prevent the reactant gas from contaminating the inner wall of the reactor chamber.

Referring to FIG. 8, FIG. 10, FIG. 12 and FIG. 14, the peripheral intake port 122 is positioned proximate to the inner wall of the reactor chamber so as to reduce turbulent flow at the peripheral area and near the inner wall of the reactor chamber, prevent the reactant gas from contaminating the inner wall of the reactor chamber, and reduce the frequency of cleaning and maintaining the reactor.

With the implementation of the embodiment of the present invention, it is easy to process and produce a subsidiary inlet module in a conventional inlet system, block, separate and guide a reactant gas, enhance the growth rate and uniformity of thickness of a semiconductor thin-film effectively, reduce contamination and a waste of the reactant gas, prevent turbulent flow from happening to a reactor chamber, and enhance the stability of the manufacturing process.

The reactant gas at the periphery of a conventional inlet system has a low utilization rate, as it is discharged mostly from the reactor chamber, thereby causing a waste of the reactant gas. In view of this, the inlet system of the present invention is characterized in that: a subsidiary inlet module is disposed outside an inlet module; and the subsidiary inlet module narrows the scope and guides the flow motion of intake of the reactant gas and thus enhances the utilization rate of the reactant gas.

From the perspective of the inlet module, the subsidiary inlet module insulates at least two reactant gases at the intake ports so as to reduce the likelihood that the reactant gases undergo a pre-reaction in the vicinity of the intake ports, thus clogging the intake ports. Also, due to the reduction in the likelihood of a pre-reaction and inner wall contamination, the required frequency of rinsing and maintenance decreases greatly, thereby enhancing the efficiency of operation of the MOCVD apparatus.

The features of the present invention are disclosed above by the preferred embodiment to allow persons skilled in the art to gain insight into the contents of the present invention and implement the present invention accordingly. The preferred embodiment of the present invention should not be interpreted as restrictive of the scope of the present invention. Hence, all equivalent modifications or amendments made to the aforesaid embodiment should fall within the scope of the appended claims.

What is claimed is:

1. An inlet system for a metal-organic chemical vapor deposition (MOCVD) apparatus, comprising:
an inlet module for admitting at least a reactant gas; and
a subsidiary inlet module disposed outside the inlet module, including at least a subsidiary inlet channel, and admitting a carrier gas.

2. The inlet system of claim 1, wherein the subsidiary inlet module includes the at least two subsidiary inlet channels, namely a first subsidiary inlet channel and a second subsidiary inlet channel, wherein the first subsidiary inlet channel is disposed outside the second subsidiary inlet channel, and the second subsidiary inlet channel is disposed outside the inlet module.

3. The inlet system of claim 1, wherein the at least a subsidiary inlet channel has one of an annular intake port, separate linear intake ports, and separate dotted intake ports.

4. The inlet system of claim 2, wherein the at least a subsidiary inlet channel has one of an annular intake port, separate linear intake ports, and separate dotted intake ports.

5. An inlet system for a metal-organic chemical vapor deposition (MOCVD) apparatus, comprising:
a inlet module including at least a first reacting gas channel for admitting a first reactant gas and at least a second reacting gas channel for admitting a second reactant gas; and
a subsidiary inlet module including at least a subsidiary inlet channel adapted to admit a carrier gas and disposed between the at least a first reacting gas channel and the at least a second reacting gas channel to separate the at least a first reacting gas channel and the at least a second reacting gas channel.

6. The inlet system of claim 5, wherein the at least a subsidiary inlet channel has at least an annular intake port, and the at least an annular intake port is disposed outside one of the at least a first reacting gas channel and the at least a second reacting gas channel.

7. The inlet system of claim 6, wherein the at least a first reacting gas channel and the at least a second reacting gas channel alternate with each other and are spaced apart from each other.

8. The inlet system of claim 7, wherein the subsidiary inlet channel further includes at least a peripheral intake port disposed outside the at least an annular intake port, the at least a first reacting gas channel, and the at least a second reacting gas channel, wherein the at least a peripheral intake port has one of a peripheral annular intake port, separate linear intake ports, and separate dotted intake ports.

9. The inlet system of claim 5, wherein the at least a subsidiary inlet channel has a plurality of linear intake ports arranged radiately, wherein the linear intake ports are each disposed between the at least a first reacting gas channel and the at least a second reacting gas channel.

10. The inlet system of claim 9, wherein the subsidiary inlet channel further includes at least a peripheral intake port disposed outside the at least a first reacting gas channel and the at least a second reacting gas channel, wherein the at least a peripheral intake port has one of a peripheral annular intake port, separate linear intake ports, and separate dotted intake ports.

11. The inlet system of claim 5, wherein the at least a subsidiary inlet channel has a plurality of linear intake ports being parallel and each disposed between the at least a first reacting gas channel and the at least a second reacting gas channel.

12. The inlet system of claim 11, wherein the subsidiary inlet channel further includes at least a peripheral intake port disposed outside the at least a first reacting gas channel and the at least a second reacting gas channel, wherein the at least a peripheral intake port has one of a peripheral annular intake port, separate linear intake ports, and separate dotted intake ports.

13. The inlet system of claim 5, wherein the at least a subsidiary inlet channel has a plurality of transverse linear intake ports and a plurality of longitudinal linear intake ports, wherein the transverse linear intake ports each share a point of contact with a corresponding one of the longitudinal linear intake ports so as to surround one of the at least a first reacting gas channel and the at least a second reacting gas channel.

14. The inlet system of claim 13, wherein the subsidiary inlet channel further includes at least a peripheral intake port disposed outside the at least a first reacting gas channel and the at least a second reacting gas channel, wherein the at least a peripheral intake port has one of a peripheral annular intake port, separate linear intake ports, and separate dotted intake ports.
